(19) United States
(12) Patent Application Publication
(10) Pub. No.: US 2016/0189979 A1
(43) Pub. Date: Jun. 30, 2016

(54) METHOD FOR PRODUCING WIRING BOARD

(71) Applicant: KYOCERA Circuit Solutions, Inc., Kyoto (JP)

(72) Inventor: Yoshinori NAKATOMI, Nagahama-shi (JP)

(73) Assignee: KYOCERA Circuit Solutions, Inc., Kyoto (JP)

(21) Appl. No.: 14/963,630

(22) Filed: Dec. 9, 2015

(30) Foreign Application Priority Data
Dec. 27, 2014 (JP) 2014-266823

(51) Int. Cl. H01L 21/48; H01L 21/56

(52) U.S. Cl. CPC H01L 21/4853; H01L 21/56; H01L 21/486

(57) ABSTRACT

The method for producing a wiring board according to the present invention includes the steps of: preparing an insulating board including a cavity forming area and a wiring forming area; forming a first wiring conductor in the wiring forming area; forming a cavity in the cavity forming area and an opening in a part of the wiring forming area; inserting an electronic component including an external electrode into the cavity; forming insulating layers on upper and lower surfaces of the insulating board, the insulating layers filled into a gap in the cavity and into the opening; forming a through-hole penetrating through the opening from the insulating layer on an upper surface side to the insulating layer on a lower surface side; and forming a second wiring conductor on a surface of the insulating layer and in the through-hole.

### BACKGROUND OF THE INVENTION

1. Technical Field

The present invention relates to a method for producing a wiring board including built-in electronic components, housing thin electronic components, in the cavity provided in the insulating board.

2. Background

The wiring board B produced by the conventional production method will be described with reference to FIG. 5. The wiring board B includes an insulating board 21, an insulating layer 22a of the upper surface side, an insulating layer 22b of the lower surface side, a first wiring conductor 23a, a second wiring conductor 23b, a solder resist layer 24, and an electronic component D′. Such a wiring board is described, for example, in Japanese Unexamined Patent Application Publication No. 2002-198654.

In the insulating board 21, a cavity 25 housing the electronic component D′ is formed. In the cavity 25, the electronic component D′ is housed in a state of being fixed by the insulating layer 22a of the upper surface side and the insulating layer 22b of the lower surface side. The electronic component D′ includes external electrodes T′ at both side ends. Examples of the electronic component D′ include a chip capacitor and the like can be cited. Furthermore, in the insulating board 21, a plurality of first through-holes 26a are formed. On the surface of the insulating board 21 and inside the first through-holes 26a, the first wiring conductor 23a is deposited. The first wiring conductors 23a of the top and bottom of the insulating board 21 are electrically connected to each other through the first through-hole 26a.

In the insulating layers 22a and 22b formed on the upper and the lower surfaces of the insulating board 21, a plurality of via holes 27 are formed. A plurality of second through-holes 26b to whose inner surface the external electrode T′ is exposed are formed from the insulating layer 22a of the upper surface side to the insulating layer 22b of the lower surface side. The second wiring conductors 23b are deposited on the surfaces of the insulating layers 22a and 22b of the upper surface side and the lower surface side, inside the via hole 27, and inside the second through-hole 26b.

A part of the second wiring conductor 23b formed on the upper surface of the insulating layer 22a of the upper surface side is electrically connected to the first wiring conductor 23a formed on the upper surface of the insulating board 21 through the via hole 27. A part of the second wiring conductor 23b formed on the lower surface of the insulating layer 22b of the lower surface side is electrically connected to the first wiring conductor 23a formed on the lower surface of the insulating board 21 through the via hole 27. The second wiring conductor 23b deposited inside the second through-hole 26b is electrically connected to the external electrode T′ of the electronic component D′.

A part of the second wiring conductor 23b formed on the surface of the insulating layer 22a of the upper surface side is exposed in the upper surface opening 24a formed in the solder resist layer 24 to form a semiconductor element connection pad 28. The electrode of the semiconductor element is connected to the semiconductor element connection pad 28 through the solder bump, whereby the semiconductor element is mounted on the upper surface of the wiring board B.

A part of the second wiring conductor 23b formed on the surface of the insulating layer 22b of the lower surface side is exposed in the lower surface opening 24b formed in the solder resist layer 24 to form an external connection pad 29 for being connected to an external electric circuit board. The external connection pad 29 and the wiring conductor of the external electric circuit board are connected, whereby the semiconductor element is electrically connected to the external electric circuit board. As a result, the signal is transmitted between the semiconductor element and the external electric circuit board through the first and the second wiring conductors 23a and 23b and the electronic component D′, whereby the semiconductor element is operated.

Next, the conventional method for producing the wiring board B will be described with reference to FIGS. 6A to 7L. FIGS. 6A to 7L show principal part schematic cross-sectional views for each of the producing processes. The same members as in the wiring board B shown in FIG. 5 will be denoted by the same reference characters, and a detailed description thereof will be omitted.

As shown in FIG. 6A, the insulating board 21 including a cavity forming area X′ and a wiring forming area Y′ is prepared. The wiring forming area Y′ surrounds the cavity forming area X′. The insulating board 21 is formed, for example, by an insulating board where the glass fiber G′ is impregnated with an epoxy resin, a bismaleimide triazine resin, and the like being thermally cured. Next, as shown in FIG. 6B, the first through-hole 26a is formed in the wiring forming area Y′. Next, as shown in FIG. 6C, on the upper and the lower surfaces of the insulating board 21 and inside the first through-hole 26a, the first wiring conductor 23a is formed.

Next, as shown in FIG. 6D, the cavity 25 is formed, for example, by the laser processing being performed along the boundary between the cavity forming area X′ and the wiring forming area Y′. Next, as shown in FIG. 6E, the insulating board 21 is placed on the adhesive sheet N′. Then, as shown in FIG. 6F, the electronic component D′ is inserted into the cavity 25 and placed on the adhesive sheet N′ exposed inside the cavity 25.

Next, as shown in FIG. 6G, the insulating layer 22a of the upper surface side is formed on the upper side of the insulating board 21. A part of the insulating layer 22a of the upper surface side enters the cavity 25 and adheres to the electronic component D′. Thereby, the electronic component D′ is fixed to the predetermined position in the cavity 25. Next, as shown in FIG. 6H, the adhesive sheet N′ is peeled off. Next, as shown in FIG. 7I, the insulating layer 22b of the lower surface side is formed on the lower side of the insulating board 21. A part of the insulating layer 22b of the lower surface side enters the cavity 25 to adhere to the electronic component D′. Thereby, the electronic component D′ is sealed in the cavity 25.

Next, as shown in FIG. 7J, a plurality of via holes 27 and a plurality of second through-holes 26b are formed in the insulating layers 22a and 22b of the upper surface side and the lower surface side by laser processing. The via hole 27 sets the first wiring conductor 23a of the upper and lower surfaces of the insulating board 21 as the bottom surface. The external electrode T′ is exposed on the inner surface of the second through-hole 26b. Next, as shown in FIG. 7K, the second wiring conductor 23b is deposited on the surfaces of the insulating layers 22a and 22b of the upper surface side and the lower surface side, inside the via hole 27, and inside the second through-hole 26b.

Lastly, as shown in FIG. 7L, the solder resist layer 24 is deposited on the upper surface of the insulating layer 22a of the upper surface side and the lower surface of the insulating layer 22b of the lower surface side, whereby the wiring board B is formed. The solder resist layer 24 includes the first opening 24a and the second opening 24b exposing a part of the second wiring conductor 23b formed on the surfaces of the insulating layers 22a and 22b of the upper surface side and the lower surface side.

In the case of forming the wiring board B in such a way, it is necessary to expose the external electrode T′ on the inner surface of the second through-hole 26b when the second through-hole 26b is formed by using a laser beam. For this reason, the laser beam is irradiated on a part of the external electrode T′. However, it is necessary to increase the output of the laser beam so as to perforate the insulating board 21 including a hard glass fiber G′ having difficulty in processing. Therefore, there are problems that the external electrode T′ to which the large-output laser beam is irradiated is damaged, the electronic component D′ is broken, and the semiconductor element does not operate stably.

### SUMMARY

The present invention has an object to provide a method for producing the wiring board allowing the semiconductor element to operate stably by avoiding the electronic component being broken in the producing processes of the wiring board.

The method for producing a wiring board according to an embodiment of the present invention includes the steps of: preparing an insulating board including a cavity forming area and a wiring forming area surrounding the cavity forming area; forming a first wiring conductor in the wiring forming area; forming a cavity in the cavity forming area and an opening connected to the cavity in a part of the wiring forming area; inserting an electronic component including an external electrode into the cavity so that the external electrode is adjacent to the opening; forming insulating layers on upper and lower surfaces of the insulating board, the insulating layers to be filled into a gap in the cavity to fix the electronic component and into the opening; forming a through-hole penetrating through the opening from the insulating layer on an upper surface side to the insulating layer on a lower surface side, the external electrode being exposed to an inner surface of the through-hole; and forming a second wiring conductor on a surface of the insulating layer and in the through-hole, the second wiring conductor electrically connected to the external electrode exposed to the inner surface.

According to the method for producing the wiring board according to the embodiment of the present invention, the opening to be connected to the cavity is also formed in the insulating board, in addition to the cavity. Then, the electronic component is inserted into the cavity, and the insulating layers formed on the upper and lower surfaces of the insulating board are made to enter the gap between the cavity and the electronic component, and the opening. Then, the through-hole to whose inner surface the external electrode is exposed, the through-hole penetrating through the opening from the insulating layer of the upper surface side to the insulating layer of the lower surface side is formed. Thus, in the portion where the through-hole is to be formed in the insulating board, the opening is formed and the glass fiber in the portion is removed beforehand, whereby the insulating layer without containing glass fiber can be perforated by a small-output laser beam when the through-hole is formed. Thereby, the method for producing the wiring board preventing the electronic component from being broken even when the laser beam is irradiated to the external electrode and allowing the semiconductor element to operate stably can be provided.

### BRIEF DESCRIPTION OF THE DRAWINGS

FIG. 1 is a schematic cross-sectional view showing a wiring board produced by the production method according to one embodiment of the present invention;

FIGS. 2A to 2H are principal part schematic cross-sectional views for respective processes for illustrating the production method according to the one embodiment of the present invention;

FIGS. 3I to 3L are principal part schematic cross-sectional views for respective processes for illustrating the production method according to the one embodiment of the present invention;

FIG. 4 is a principal part enlarged plan view for illustrating the production method according to the one embodiment of the present invention;

FIG. 5 is a schematic cross-sectional view showing a wiring board produced by the conventional production method;

FIGS. 6A to 6H are principal part schematic cross-sectional views for respective processes for illustrating the conventional production method; and

FIGS. 7I to 7L are principal part schematic cross-sectional views for respective processes for illustrating the conventional production method.

### DETAILED DESCRIPTION

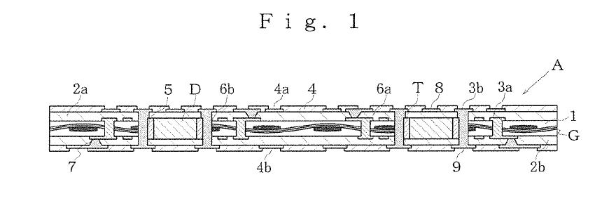

First, the wiring board A produced by the method for producing the wiring board according to the one embodiment will be described with reference to FIG. 1. The wiring board A includes an insulating board 1, an insulating layer 2a of the upper surface side, an insulating layer 2b of the lower surface side, a first wiring conductor 3a, a second wiring conductor 3b, a solder resist layer 4, and an electronic component D.

In the insulating board 1, a cavity 5 housing the electronic component D is formed. In the cavity 5, the electronic component D is housed in a state of being fixed by the insulating layer 2a of the upper surface side and the insulating layer 2b of the lower surface side. The electronic component D includes external electrodes T at both side ends. Examples of the electronic component D include a chip capacitor and the like. Furthermore, in the insulating board 1, a plurality of first through-holes 6a are formed. On the surface of the insulating board 1 and inside the first through-hole 6a, the first wiring conductor 3a is deposited. The first wiring conductors 3a of the top and bottom of the insulating board 1 are electrically connected to each other through the first through-hole 6a.

In the insulating layers 2a and 2b formed on the upper and the lower surfaces of the insulating board 1, a plurality of via holes 7 are formed. A plurality of second through-holes 6b to whose inner surface the external electrode T is exposed are formed from the insulating layer 2a of the upper surface side to the insulating layer 2b of the lower surface side. The second wiring conductors 3b are deposited on the surfaces of the insulating layers 2a and 2b of the upper surface side and the lower surface side, inside the via hole 7, and inside the second through-hole 6b.

A part of the second wiring conductor 3b formed on the upper surface of the insulating layer 2a of the upper surface side is electrically connected to the first wiring conductor 3a formed on the upper surface of the insulating board 1 through the via hole 7. A part of the second wiring conductor 3b formed on the lower surface of the insulating layer 2b of the lower surface side is electrically connected to the first wiring conductor 3a formed on the lower surface of the insulating board 1 through the via hole 7. The second wiring conductor 3b deposited inside the second through-hole 6b is electrically connected to the external electrode T of the electronic component D.

A part of the second wiring conductor 3b formed on the surface of the insulating layer 2a of the upper surface side is exposed in the upper surface opening 4a formed in the solder resist layer 4 to form the semiconductor element connection pad 8. The electrode of the semiconductor element is connected to the semiconductor element connection pad 8 through the solder bump, whereby the semiconductor element is mounted on the upper surface of the wiring board A.

A part of the second wiring conductor 3b formed on the surface of the insulating layer 2b of the lower surface side is exposed in the lower surface opening 4b formed in the solder resist layer 4 to form the external connection pad 9 for being connected to an external electric circuit board. The external connection pad 9 and the wiring conductor of the external electric circuit board are connected, whereby the semiconductor element is electrically connected to the external electric circuit board. As a result, the signal is transmitted between the semiconductor element and the external electric circuit board through the first and the second wiring conductors 3a and 3b and the electronic component D, whereby the semiconductor element is operated.

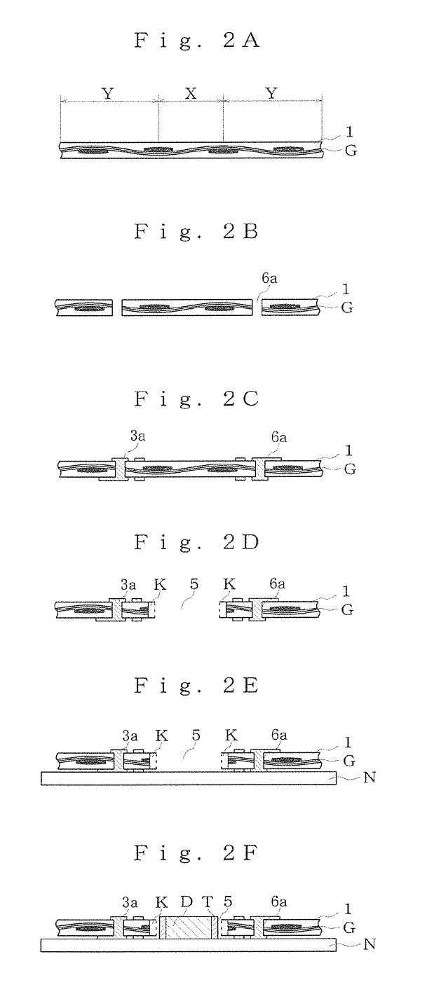

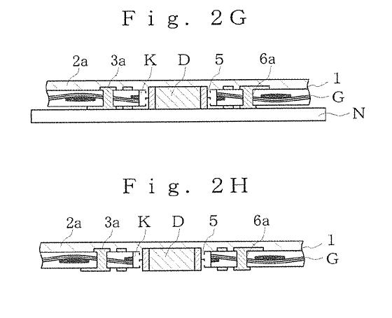

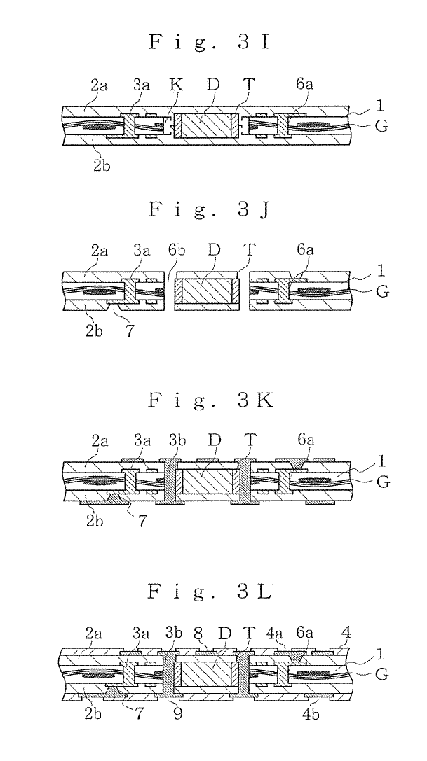

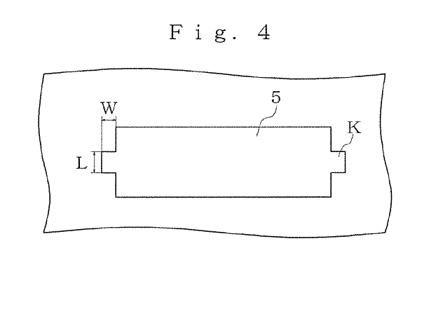

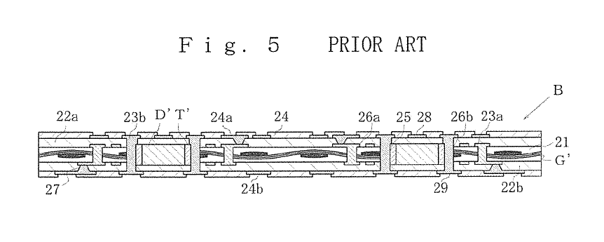

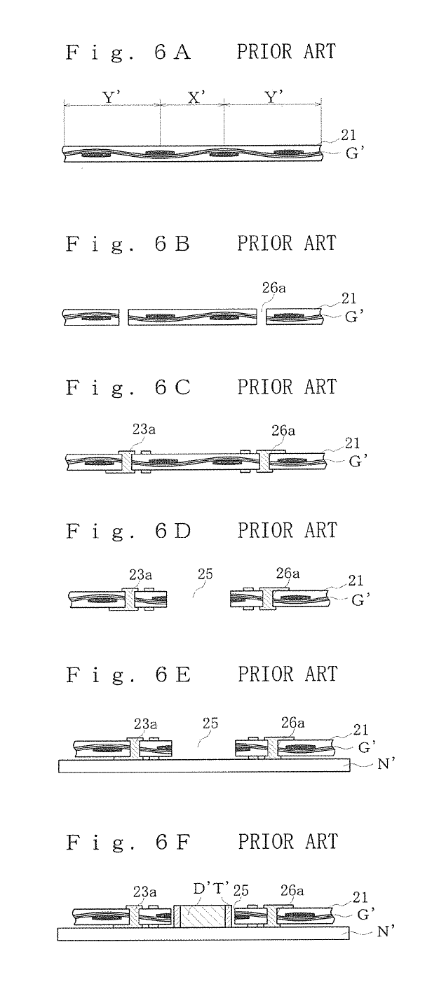

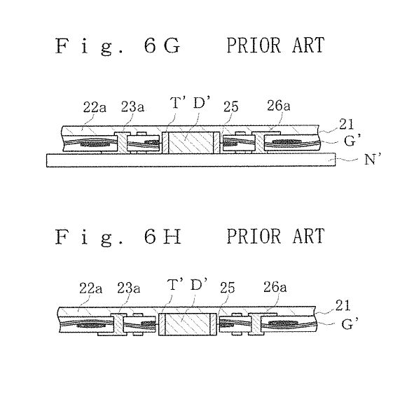

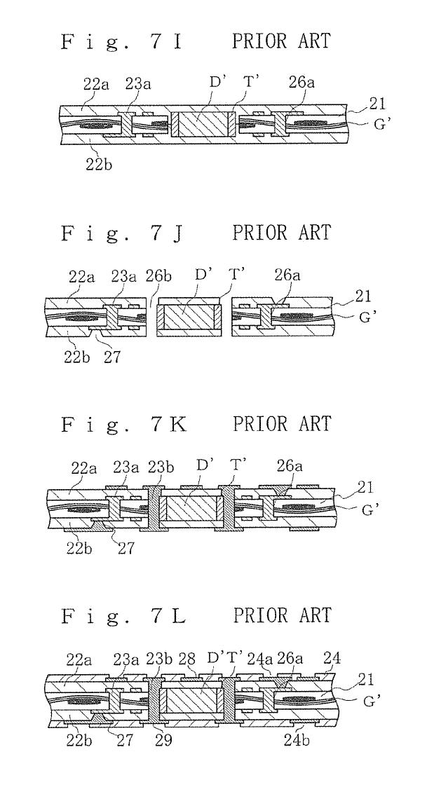

Next, the method for producing the wiring board according to the embodiment will be described with reference to FIGS. 2A to 3L. FIGS. 2A to 3L show principal part schematic cross-sectional views for each of the producing processes. The same members as in the wiring board A shown in FIG. 1 will be denoted by the same reference characters, and a detailed description thereof will be omitted.

As shown in FIG. 2A, the insulating board 1 including a cavity forming area X and a wiring forming area Y are prepared. The wiring forming area Y surrounds the cavity forming area X. The insulating board 1 is formed, for example, by the electrical insulating material, where the glass fiber G is impregnated with an epoxy resin, a bismaleimide triazine resin, and the like being thermally cured. The thickness of the insulating layer 1 is preferably about 40 to 600 μm.

Next, as shown in FIG. 2B, the first through-hole 6a is formed in the wiring forming area Y. The diameter of the first through-hole 6a is preferably about 50 to 300 μm, and is formed by, for example, drilling processing, laser processing, or blast processing. Next, as shown in FIG. 2C, on the upper and the lower surfaces of the insulating board 1 and inside the first-through-hole 6a, the first wiring conductor 3a is formed. The first wiring conductor 3a is formed of a highly conductive metal such as copper by, for example, the well-known semi-additive method or subtractive method.

Next, as shown in FIG. 2D, the cavity 5 is formed in the cavity forming area X, and the opening K to be connected to the cavity 5 is formed in a part of the wiring forming area Y. The cavity 5 and the opening K may be formed concurrently, and the opening K may be formed after the cavity 5 is formed. The cavity 5 and the opening K are formed by, for example, laser processing or blast processing. The shape in a top view of the cavity 5 and the opening K is shown in FIG. 4. The size of the opening K has a longitudinal dimension L of preferably about 100 to 300 μm, and a lateral dimension W of preferably about 50 to 250 μm.

Next, as shown in FIG. 2E, the insulating board 1 is placed on the adhesive sheet N. Then, as shown in FIG. 2F, the electronic component D is inserted into the cavity 5 and placed on the adhesive sheet N exposed inside the cavity 5.

Next, as shown in FIG. 2G, the insulating layer 2a of the upper surface side is formed on the upper side of the insulating board 1. A part of the insulating layer 2a of the upper surface side enters the cavity 5 and the opening K, and adheres to the electronic component D. Thereby, the electronic component D is fixed to the predetermined position in the cavity 5. Furthermore, the upper surface side of the opening K is covered by the insulating layer 2a. In order to form the insulating layer 2a of the upper surface side, the method for laminating the uncured resin sheets for the insulating layer 2a of the upper surface side onto the upper surface of the insulating board 1, and the method for performing the heat processing while pressing the sheets from above are employed. The insulating layer 2a of the upper surface side includes electrical insulating materials containing a thermosetting resin such as an epoxy resin and a polyimide resin, and has the thickness of preferably about 15 to 70 μm.

Next, as shown in FIG. 2H, the adhesive sheet N is peeled off. Next, as shown in FIG. 3I, the insulating layer 2b of the lower surface side is formed on the lower side of the insulating board 1. A part of the insulating layer 2b of the lower surface side enters the cavity 5 and the opening K, and adheres to the electronic component D. Thereby, the electronic component D is sealed in the cavity 5. Furthermore, the lower surface side of the opening K is covered by the insulating layer 2b. The insulating layer 2b of the lower surface side includes electrical insulating materials containing a thermosetting resin such as an epoxy resin and a polyimide resin, and has the thickness of preferably about 15 to 70 μm.

Next, as shown in FIG. 3J, a plurality of via holes 7 and a plurality of second through-holes 6b are formed in the insulating layers 2a and 2b of the upper surface side and the lower surface side by, for example, laser processing. The via hole 7 sets the first wiring conductor 3a of the upper and lower surfaces of the insulating board 1 as the bottom surface, and has the diameter of preferably about 20 to 100 μm. The second through-hole 6b is formed in the opening K. The external electrode T is exposed on the inner surface of the second through-hole 6b. The opening K does not include a glass cloth inside, and is filled only with the resin, and therefore the second through-hole 6b can be formed by a small-output laser beam. Therefore, it is possible to form the second through-hole 6b without causing serious damage to the external electrode T of the electronic component D. The diameter of the second through-hole 6b is preferably about 50 to 250 μm.

Next, as shown in FIG. 3K, the second wiring conductor 3b is deposited on the surfaces of the insulating layers 2a and 2b of the upper surface side and the lower surface side, inside the via hole 7, and inside the second through-hole 6b. The second wiring conductor 3b is formed of a highly conductive metal such as copper by, for example, the well-known semi-additive method.

Lastly, as shown in FIG. 3L, the solder resist layer 4 is deposited on the upper surface of the insulating layer 2a of the upper surface side and the lower surface of the insulating layer 2b of the lower surface side, whereby the wiring board A is formed. The solder resist layer 4 includes the first opening 4a and the second opening 4b exposing a part of the second wiring conductor 3b formed on the surfaces of the insulating layers 2a and 2b of the upper surface side and the lower surface side. For example, the resin paste or film made of electrically insulating materials containing a thermosetting resin such as an epoxy resin and a polyimide resin is applied or adheres onto the insulating layers 2a and 2b of the upper and the lower surface sides and the second wiring conductor 3b, to be thermally cured, whereby the solder resist layer 4 is formed.

As described above, according to the method for producing the wiring board according to the one embodiment, the opening K to be connected to the cavity 5 is also formed in the insulating board 1, in addition to the cavity 5. Then, the electronic component D is inserted into the cavity 5, and the insulating layers 2a and 2b formed on the upper and lower surfaces of the insulating board 1 are made to enter the gap between the cavity 5 and the electronic component D, and the opening K. Then, the second through-hole 6b to whose inner surface the external electrode T is exposed, the second through-hole 6b penetrating through the opening K is formed from the insulating layer 2a of the upper surface side to the insulating layer 2b of the lower surface side. Thus, in the portion where the second through-hole 6b is to be formed in the insulating board 1, the opening K is formed and the glass fiber G in the portion is removed beforehand.

For this reason, when the second through-hole 6b is formed, the insulating layers 2a and 2b of the upper surface side and the lower surface side without including the glass fiber G can be perforated by the small-output laser beam. Even when the laser beam is irradiated on the external electrode T, the output of the laser beam is small, and therefore the damage to the electronic component D can be prevented. Therefore, the wiring board capable of stably operating the semiconductor element can be obtained.

The present invention is not limited to the one embodiment described above, and various modifications are possible as long as they are within the scope of the claims. For example, in the method for producing the wiring board according to the one embodiment described above, although the second through-hole 6b is formed by laser processing, it may be formed by blast processing. Even when the second through-hole 6b is formed by blast processing, the ejection pressure of the abrasive grains can be reduced so as to perforate the insulating layer without including glass fiber. Therefore, the wiring board capable of preventing damage to the electronic component and capable of stably operating the semiconductor element can be obtained.

Furthermore, in the method for producing the wiring board according to the one embodiment described above, resin and glass fiber G are used as the material of the insulating board 1. However, instead of the glass fiber G, for example, other fibrous reinforcing materials such as an aramid fiber may be used.

What is claimed is:

1. A method for producing a wiring board, the method comprising the steps of:
preparing an insulating board including a cavity forming area and a wiring forming area surrounding the cavity forming area;
forming a first wiring conductor in the wiring forming area;
forming a cavity in the cavity forming area and an opening connected to the cavity in a part of the wiring forming area;
inserting an electronic component including an external electrode into the cavity so that the external electrode is adjacent to the opening;
forming insulating layers on upper and lower surfaces of the insulating board, the insulating layers to be filled into a gap in the cavity to fix the electronic component and into the opening;
forming a through-hole penetrating through the opening from the insulating layer on an upper surface side to the insulating layer on a lower surface side, the external electrode being exposed to an inner surface of the through-hole; and
forming a second wiring conductor on a surface of the insulating layer and in the through-hole, the second wiring conductor electrically connected to the external electrode exposed to the inner surface.

2. The method for producing a wiring board according to claim 1, wherein the insulating board includes a fibrous reinforcement material.

3. The method for producing a wiring board according to claim 2, wherein the fibrous reinforcing material is a glass fiber.

4. The method for producing a wiring board according to claim 1, wherein the cavity and the opening are formed concurrently.
